(19) United States
(12) Patent Application Publication
(10) Pub. No.: US 2026/0096252 A1
(43) Pub. Date: Apr. 2, 2026

(54) LIGHT EMITTING ELEMENT

(71) Applicant: NICHIA CORPORATION, Anan-shi (JP)

(72) Inventor: Takefumi NAKAGAWA, Tokushima-shi (JP)

(73) Assignee: NICHIA CORPORATION, Anan-shi (JP)

(21) Appl. No.: 19/336,898

(22) Filed: Sep. 23, 2025

(30) Foreign Application Priority Data
Sep. 27, 2024 (JP) 2024-168693

(51) Int. Cl. H10H 20/831; H10H 20/832; H10H 20/833; H10H 20/84

(52) U.S. Cl. CPC H10H 20/831; H10H 20/833; H10H 20/835; H10H 20/84

(57) ABSTRACT

A light emitting element includes: a semiconductor structure including a first semiconductor layer of a first conductivity type, an active layer disposed below the first semiconductor layer, and a second semiconductor layer of a second conductivity type disposed below the active layer; a cover part made of an insulating material and disposed on the upper surface of the first semiconductor layer; a metal layer disposed within the cover part; a light transmissive electrode disposed on the upper surface of the cover part and the upper surface of the first semiconductor layer; a first electrode including an external connection portion disposed on the upper surface of the light transmissive electrode, and an extended portion extending from the external connection portion, and a second electrode disposed on the second semiconductor layer. At least a portion of the extended portion overlaps the cover part and the metal layer in a plan view.

### CROSS REFERENCE TO RELATED APPLICATION

This application claims priority to Japanese Patent Applications No. 2024-168693, filed on Sep. 27, 2024, the entire contents of which are hereby incorporated by reference.

### BACKGROUND

### Technical Field

The present disclosure relates to a light emitting element.

### Background Art

Japanese Patent Publication No. 2018-113442 discloses a light emitting element that includes a first electrode electrically connected to a first conductivity type semiconductor layer and a second electrode positioned on a transparent electrode layer disposed on a second conductivity type semiconductor layer and electrically connected to the transparent electrode layer. It also discloses a structure in which the second electrode includes a second electrode pad and a second electrode extended portion extending from the second electrode pad, and a second reflecting layer is disposed between the second electrode and the transparent electrode layer for improving the light extraction efficiency.

### SUMMARY

Such a light emitting element is demanded to have a higher output and higher reliability. An object of the present disclosure is to provide a higher reliability light emitting element capable of achieving a higher output.

A light emitting element according one embodiment of the present invention comprises: a semiconductor structure including a first semiconductor layer of a first conductivity type, an active layer disposed below the first semiconductor layer, and a second semiconductor layer of a second conductivity type disposed below the active layer; a cover part made of an insulating material and disposed on the upper surface of the first semiconductor layer; a metal layer disposed within the cover part; a light transmissive electrode disposed on the upper surface of the cover part and the upper surface of the first semiconductor layer; a first electrode including an external connection portion disposed on the upper surface of the light transmissive electrode, and an extended portion extending from the external connection portion, and a second electrode disposed on the second semiconductor layer. At least a portion of the extended portion overlaps the cover part and the metal layer in a plan view. The external connection portion includes a first region overlapping the cover part and not overlapping the metal layer in the plan view.

A light emitting element according to another embodiment of the present invention comprises: a semiconductor structure comprising a first semiconductor layer of a first conductivity type, an active layer disposed below the first semiconductor layer, and a second semiconductor layer of a second conductivity type disposed below the active layer; a cover part disposed on the upper surface of the first semiconductor layer and containing one or more elements selected from Zr, Si, V, Nb, Hf, Ta, Al, Ce, In, Sb, and Zn, and either one or both of oxygen and nitrogen; a metal layer disposed within the cover part; a light transmissive electrode disposed on the upper surface of the cover part and the upper surface of the first semiconductor layer; a first electrode comprising an external connection portion disposed on the upper surface of the light transmissive electrode, and an extended portion extending from the external connection portion; and a second electrode disposed on the second semiconductor layer. At least a portion of the extended portion overlaps the cover part and the metal layer in the plan view. The external connection portion includes a first region overlapping the cover part and not overlapping the metal layer in the plan view.

A light emitting element according to an embodiment of the present disclosure can achieve a higher output and higher reliability.

### BRIEF DESCRIPTION OF THE DRAWINGS

FIG. 1A is a schematic plan view showing an example of a light emitting element according to Embodiment 1.

FIG. 1B is a schematic cross-sectional view taken along line 1b-1b in FIG. 1A.

FIG. 1C is a schematic partial cross-sectional view taken along line 1c-1c in FIG. 1A.

FIG. 1D is a schematic partial cross-sectional view taken along line 1d-1d in FIG. 1A.

FIG. 1E is a schematic plan view showing another example of a light emitting element according to Embodiment 1.

FIG. 1F is a schematic partially enlarged cross-sectional view of the structure directly under the extended portion in a light emitting element according to Embodiment 1.

FIG. 1G is a schematic partial cross-sectional view of the structure around the extended portion in a light emitting element according to Embodiment 1-1.

FIG. 1H is a schematic partial cross-sectional view of the structure around the external connection portion in a light emitting element according to Embodiment 1-2.

FIG. 1I is a schematic partial cross-sectional view of the structure around the extended portion in the light emitting element according to Embodiment 1-2.

FIG. 1J is a schematic partial cross-sectional view of the structure around the external connection portion in a light emitting element according to Embodiment 1-3.

FIG. 1K is a schematic partial cross-sectional view of the structure around the external connection portion in a light emitting element according to Embodiment 1-4.

FIG. 2A is a schematic plan view of a light emitting element according to Embodiment 2.

FIG. 2B is a schematic cross-sectional view taken along line 2b-2b in FIG. 2A.

FIG. 2C is a schematic partial cross-sectional taken along line 2c-2c in FIG. 2A.

FIG. 2D is a schematic partially enlarged cross-sectional view showing another example of the structure directly under the external connection portion in a light emitting element according to Embodiment 2.

FIG. 2E is a schematic partial cross-sectional view showing yet another example of the structure directly under the external connection portion in a light emitting element according to Embodiment 2.

FIG. 3A is a schematic plan view of a light emitting element according to Embodiment 3.

FIG. 3B is a schematic cross-sectional view taken along line 3b-3b in FIG. 3A.

FIG. 3C is a schematic partial cross-sectional taken along line 3c-3c in FIG. 3A.

FIG. 4 is a schematic plan view explaining a method of determining the border between the external connection portion and an extended portion of the first electrode in a light emitting element.

### DETAILED DESCRIPTION

Certain embodiments of light emitting elements according to the present invention will be described below. The drawings referenced in the description below are schematic representations of the present invention. As such, the scale, intervals, or positional relationships of the members may be exaggerated or members partially omitted. There may be a case in which the scale or intervals of members does not correspond between a plan view and a cross-sectional view. In the description below, the same designations and reference numerals denote the same or similar members as a rule, for which detailed description will be omitted as appropriate.

In the present specification, terms such as “on,” “above,” “top,” “under,” “below,” “bottom,” and the like are used to indicate relative positions of constituent elements in a drawing being referenced for explanatory purposes. These terms are not intended to indicate absolute positions unless otherwise specifically stated.

The present inventor conducted his study to provide a light emitting element having a higher output and higher reliability, and came to the idea of disposing a metal layer between an electrode and a semiconductor structure to thereby reduce the light absorption by the electrode and increase the output of a light emitting element. As a result of the inventor's further study, it was found for the first time that, in the case of a light emitting element having a metal layer, wire bonding the external connection portion of the electrode makes the electrode more susceptible to separation from the semiconductor layer. Based on these findings, the present inventor completed a light emitting element that can increase the output with the provision of a metal layer while reducing the chances of separation of the electrode during wire bonding.

Light emitting elements according to Embodiments 1 to 3 of the present invention will be explained below.

### Embodiment 1

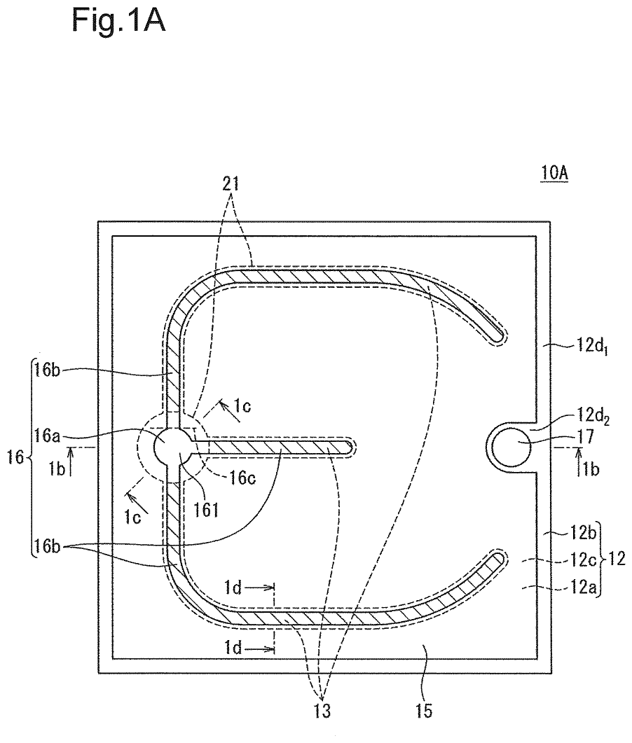

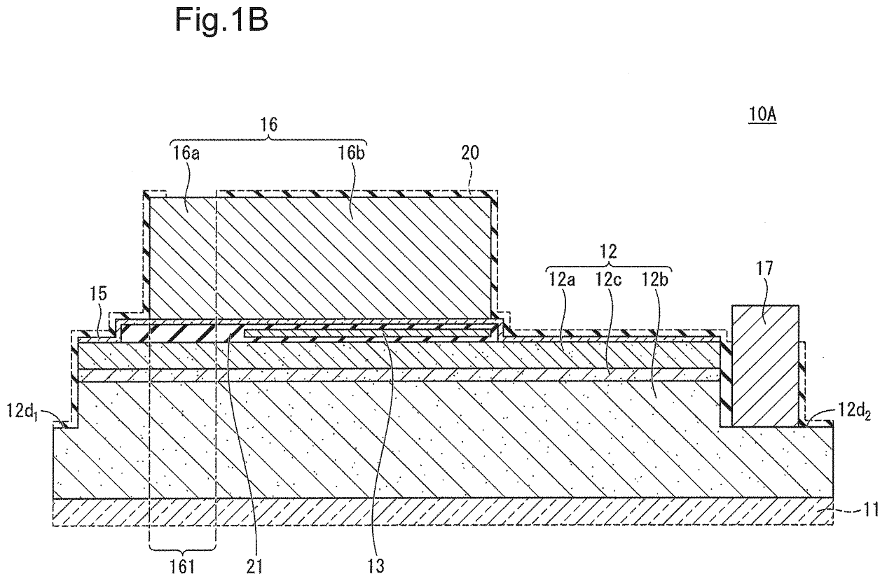

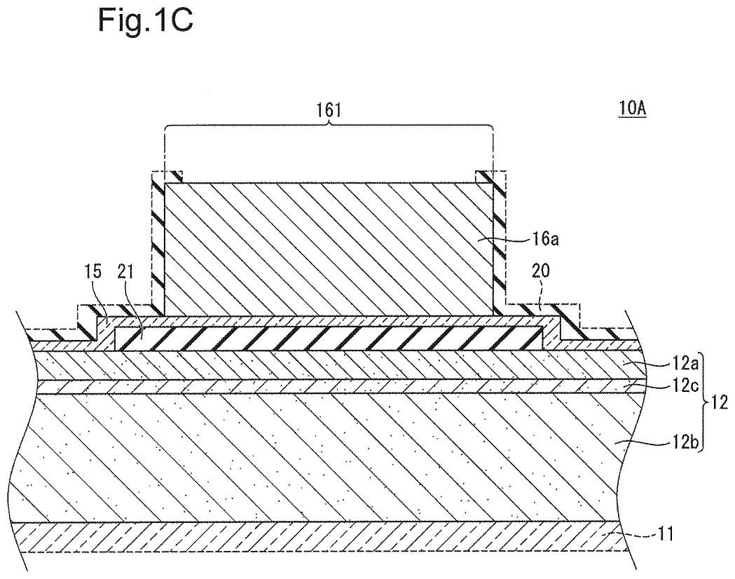

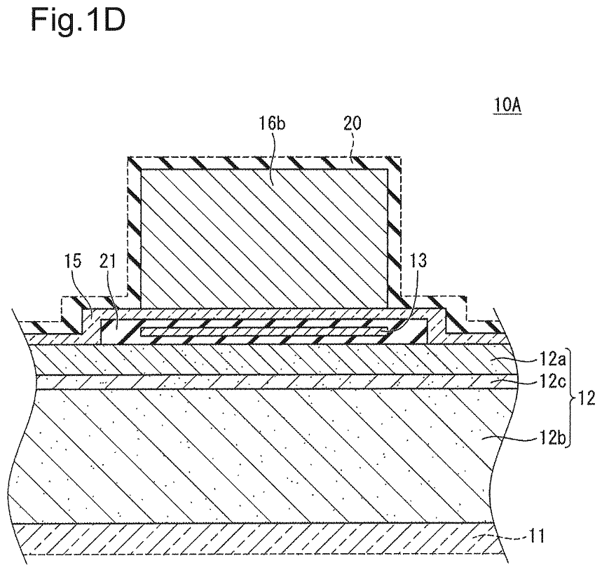

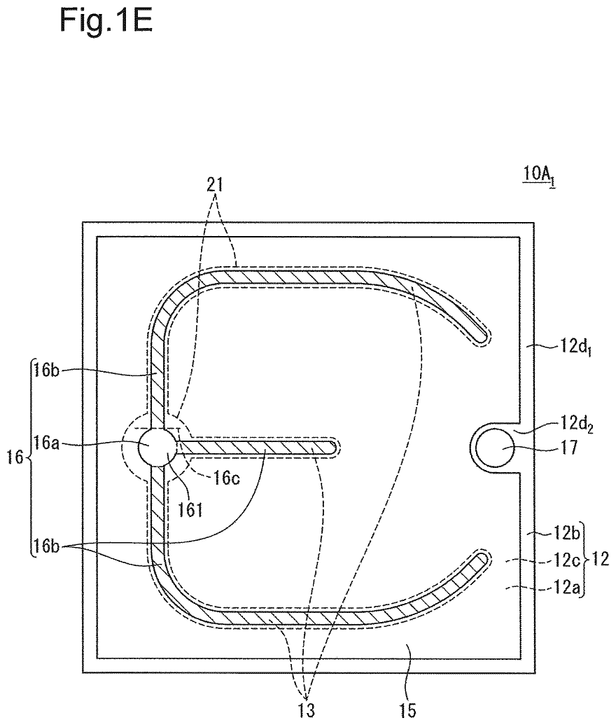

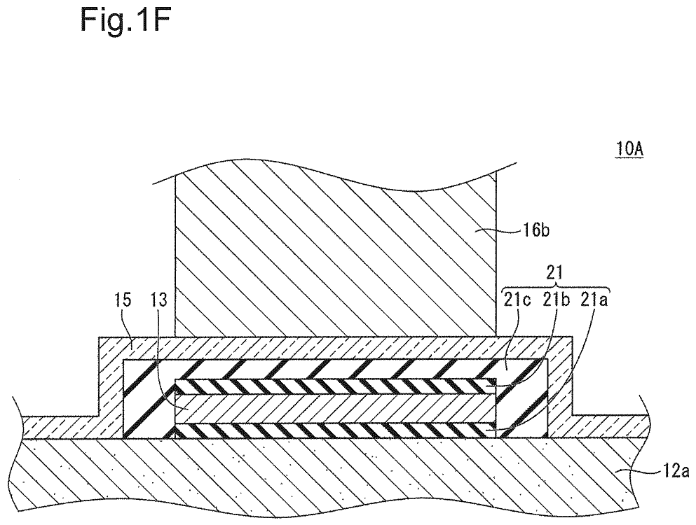

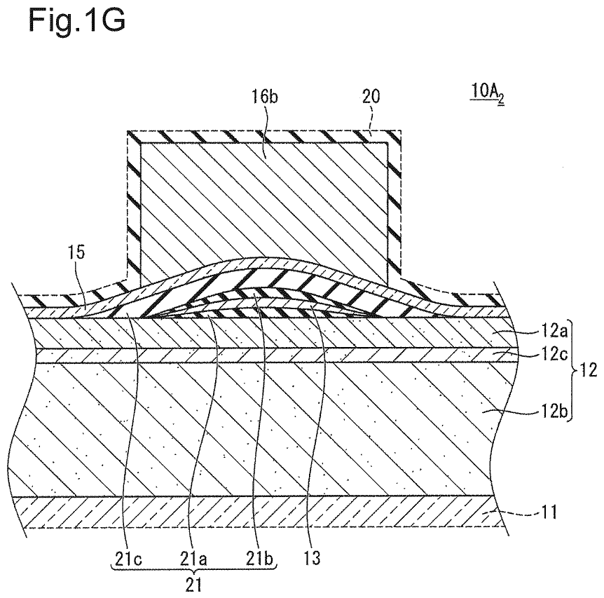

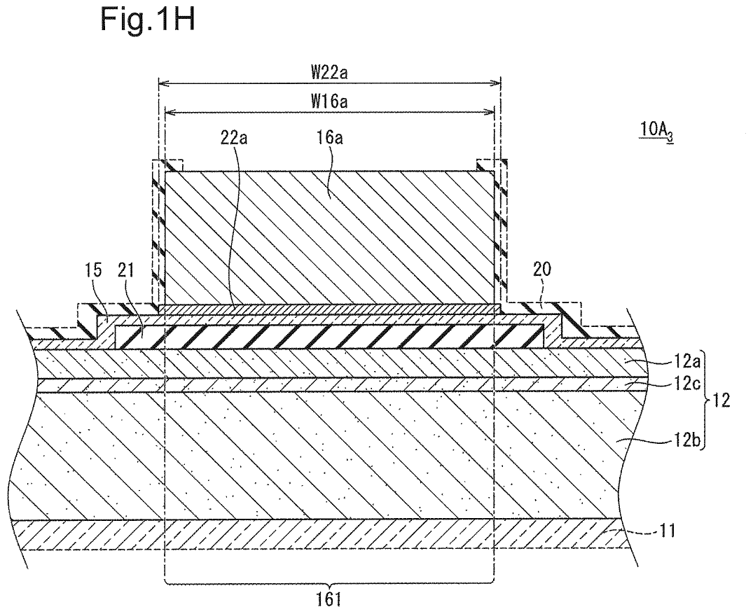

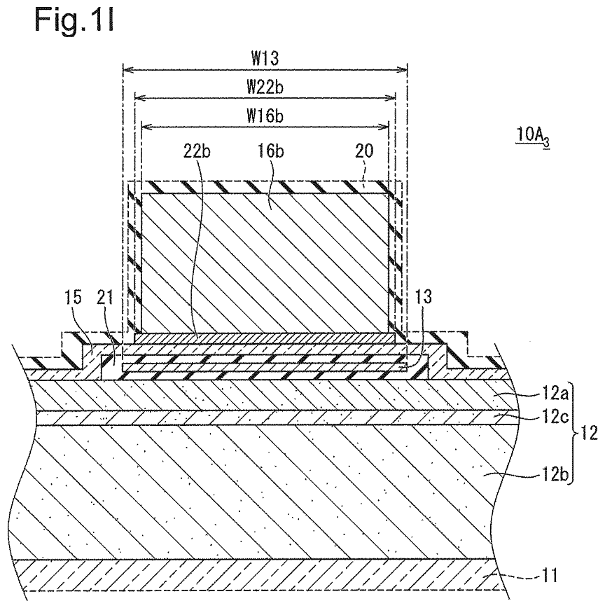

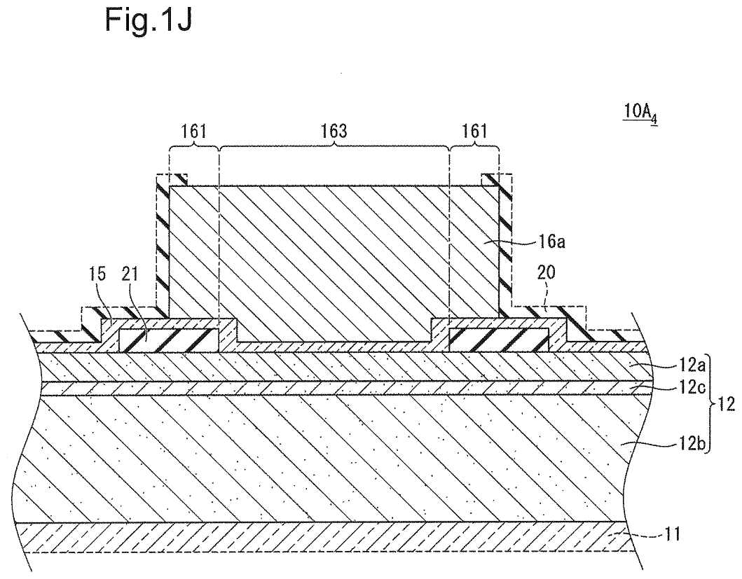

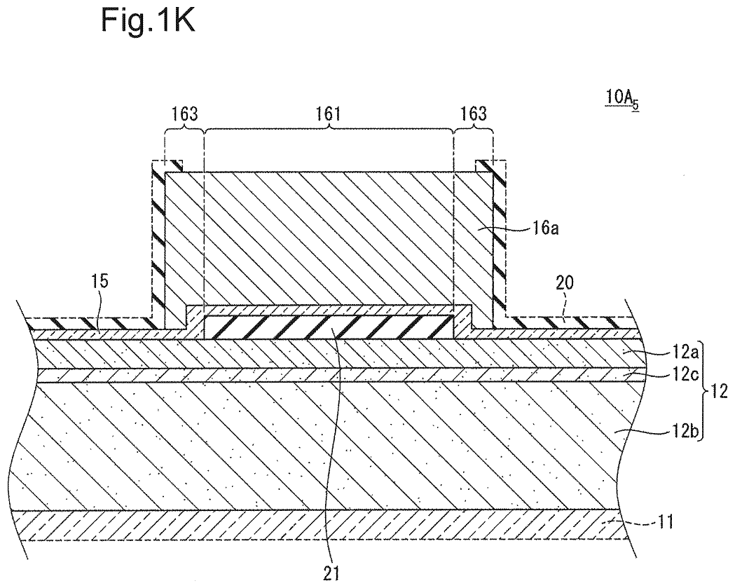

FIG. 1A is a schematic plan view of a light emitting element 10A according to Embodiment 1. FIG. 1B is a schematic cross-sectional view taken along 1b-1b in FIG. 1A. FIG. 1C is a schematic partial cross-sectional view taken along line 1c-1c in FIG. 1A, primarily showing the structure around the external connection portion 16a of the first electrode 16. FIG. 1D is a schematic partial cross-sectional view taken along line 1d-1d in FIG. 1A primarily showing the structure around the extended portion 16b of the first electrode 16.

The light emitting element 10A according to this embodiment includes a semiconductor structure 12, a cover part 21, a metal layer 13, a light transmissive electrode 15, a first electrode 16, and a second electrode 17. The light emitting element 10A preferably includes a protective layer 20 covering the semiconductor structure 12, the light transmissive electrode 15, the first electrode 16, and the second electrode 17. The light emitting element 10A shown in FIG. 1A is in the state in which a protective layer 20 is absent. The light emitting element 10A may include a substrate 11 under the semiconductor structure 12 for supporting the semiconductor structure 12.

The semiconductor structure 12 has a first conductivity type first semiconductor layer 12a, an active layer 12c disposed below the first semiconductor layer 12a, and a second conductivity type second semiconductor layer 12b disposed below the active layer 12c. The cover part 21 is made of an insulating material and disposed on the upper surface of the first semiconductor layer 12a. The metal layer 13 is disposed within the cover part 21. A light transmissive electrode 15 is disposed on the upper surface of the cover part 21 and the upper surface of the first semiconductor layer 12a. The first electrode 16 includes an external connection portion 16a and an extended portion 16b extending from the external connection portion 16a disposed on the upper surface of the light transmissive electrode 15. The second electrode 17 is disposed on the second semiconductor layer 12b.

In a plan view of the light emitting element 10A, at least a portion of the extended portion 16b overlaps the cover part 21 and the metal layer 13.

In the present specification, the term “plan view” refers to viewing the light emitting element 10A from the first electrode 16 side. In the example of light emitting element 10A shown in FIG. 1A, the metal layer 13 is located in areas indicated by hatching and partially overlaps each of the three extended portions 16b.

As can be understood from FIG. 1B and FIG. 1D, at least a portion of the light that traveling from the active layer 12c to the extended portions 16b is reflected off the metal layer 13 before reaching the extended portions 16b, and thus can be extracted from the light emitting element 10A. This can reduce light absorption by the extended portions 16b, thereby improving the output of the light emitting element 10A.

The metal layer 13 may be disposed such that a portion of each extended portion 16b does not overlap the metal layer 13. In the example shown in FIG. 1A, the extended portions 16b do not overlap the metal layer 13 in the vicinity of the external connection portion 16a which is substantially circular in a plan view. This is advantageous in further enhancing the effect of lessening the separation of the external connection portion 16a described below.

From the viewpoint of further enhancing the effect of increasing the output of the light emitting element 10A, it is preferable that substantially the entireties of the extended portions 16b overlap the metal layer 13 in a plan view, as in the light emitting element 10A₁ shown in FIG. 1E.

As shown in FIG. 1B and FIG. 1C, in a plan view of the light emitting element 10A, the external connection portion 16a includes a first region 161 overlapping the cover part 21 but not overlapping the metal layer 13. Such a structure allows for inhibiting separation of the external connection portion 16a during wire bonding as will be described below.

If a metal layer 13 is disposed directly under the external connection portion 16a, the metal layer 13 would be subjected to shock when bonding a wire to the external connection portion 16a, causing the metal layer 13 to detach from the cover part 21 at the interface between the metal layer 13 and the cover part 21 directly under the external connection portion 16a. This is thought to be caused by the weak adhesion between the metal layer 13 and the cover part 21 attributable to the properties of the materials used for the metal layer 13 and the cover part 21. This separation may lead to the separation of the external connection portion 16a from the semiconductor structure 12. The separation of the external connection portion 16a may result in decrease in the reliability of the light emitting element. For example, the adhesion between the metal layer 13 and the cover part 21 is weaker than the adhesion between the semiconductor structure 12 and the cover part 21.

In the light emitting element 10A according to this embodiment, the metal layer 13 is arranged such that the external connection portion 16a includes a first region 161 directly under which the metal layer 13 is absent. That is, in a region between the external connection portion 16a and the semiconductor structure 12, the area of the interface, which is a weak adhesion region, between the metal layer 12 and the cover part 21 is reduced, thereby inhibiting the external connection portion 16a from being separated from the semiconductor structure 12 during wire bonding. This can increase the reliability of the light emitting element 10A.

In the light emitting element 10A shown in FIG. 1A, the external connection portion 16a does not overlap the metal layer 13 at all in a plan view. In other words, an entirety of the external connection portion 16a is a first region 161. Furthermore, the portions of the extended portions 16b that are adjacent to the external connection portion 16a in a plan view do not overlap the metal layer 13. With this structure, the external connection portion 16a is less likely to be separated from the semiconductor structure 12. However, the light from the active layer 12c that reaches the extended portions 16b may be increased, so that the effect of increasing the output of the light emitting element 10A may be reduced.

Each constituent element will be described in detail below.

### Semiconductor Structure 12

A semiconductor structure 12 includes a first semiconductor layer 12a of a first conductivity type, an active layer 12c disposed below the first semiconductor layer 12a, and a second semiconductor layer 12b of a second conductivity type disposed below the active layer 12c. In other words, the semiconductor structure 12 has a first semiconductor layer 12a, a second semiconductor layer 12b, and an active layer 12c positioned between the first semiconductor layer 12a and the second semiconductor layer 12b. The semiconductor structure 12 may be disposed on the upper surface of a substrate 11. The shape of the semiconductor structure 12 in a plan view is, for example, quadrangular. In the case in which the semiconductor structure 12 has a quadrangular shape in a plan view, the length of a side thereof is 100 μm to 2000 μm.

The first conductivity type is p-type or n-type. The second conductivity type is different from the first conductivity type, i.e., n-type or p-type. In this embodiment, the first conductivity type is p-type, and the second conductivity type is n-type. The active layer 12c emits light when a voltage is applied across the first electrode 16 electrically connected to the first semiconductor layer 12a and the second electrode 17 disposed on and electrically connected to the second semiconductor layer 12b.

The semiconductor structure 12 may have regions in which the first semiconductor layer 12a and the active layer 12c are not present, i.e., may have recesses formed in a surface of the first semiconductor layer 12a and include a first exposed part 12d1 and a second exposed part 12d2, each of which is a portion at which the second semiconductor layer 12b is exposed at the bottom of a respective one of the recesses.

In the example shown in FIG. 1A, a first exposed portion 12d1 and a second exposed portion 12d2 are provided along the periphery of the light emitting element 10A in a plan view. More specifically, in a plan view, a strip shaped first exposed portion 12d1 is provided along the four sides of the light emitting element 10A and a semi-elliptical second exposed portion 12d2 connected to the first exposed portion 12d1 is provided at substantially the center of one of the sides of the light emitting element 10A. A second electrode 17 is disposed at the semi-elliptical second exposed portion 12d2. The position and the shape of the second exposed portion 12d2 can be appropriately changed based on the other structural characteristics of the light emitting element. In the present specification, the first exposed portion 12d1 and the second exposed portion 12d2 might be collectively referred to as the exposed portion 12d.

For the first semiconductor layer 12a, the second semiconductor layer 12b, and the active layer 12c, nitride semiconductors such as In_{X}Al_{Y}Ga_{1-X-Y}N (0≤X, 0≤Y, X+Y<1) are used, for example.

### Cover Part 21

The cover part 21 is disposed on the upper surface of the first semiconductor layer 12a partly covering the upper surface of the first semiconductor layer 12a.

As shown in FIG. 1A, in a plan view, the outer edges of the cover part 21 are preferably located outward of the outer edges of the first electrode 16. The distance between the outer edges of the cover part 21 and the outer edges of the first electrode 16, i.e., the width of a portion of the cover part 21 located outward of the first electrode 16 is, for example, 2 μm to 7 μm.

The cover part 21 is made of an insulating material, preferably a light transmissive insulating material. Alternatively, the cover part 21 is made of a material containing one or more elements selected from Zr, Si, V, Nb, Hf, Ta, Al, Ce, In, Sb, and Zn, and either one or both of oxygen and nitrogen.

The cover part 21 made of such a material allows for reducing the likelihood of electrically connecting the metal layer 13 disposed within the cover part 21 to the light transmissive electrode 15, thereby further improving the reliability of the light emitting element 10A.

Examples of materials that can be appropriately used for the cover part 21 include oxides, nitrides, or oxynitrides of Zr, Si, V, Nb, Hf, Ta, Al, Ce, In, Sb, Zn, or the like, particularly preferably SiO₂, SiN, SiON, or the like. The material for the cover part 21 is preferably selected in consideration of the characteristics that are particularly important for the purpose, such as enhanced moisture resistance, increased output, and the like.

For example, from the viewpoint of enhancing moisture resistance, a highly moisture-proof material, for example, SiON is preferably used for the cover part 21 so that that moisture does not reach the metal layer 13 disposed within the cover part 21.

On the other hand, from the viewpoint of increasing output, a material having a lower refractive index than that of the first semiconductor layer 12a is preferably used for the cover part 21 to facilitate effective light extraction from the semiconductor structure 12. The refractive indices in the present specification refer to the refractive indices for the peak wavelength of the light emitted by the semiconductor structure 12 unless otherwise specially stated. More preferably, a material having a higher refractive index than that of the light transmissive electrode 15 is used for the cover part 21 so that the light from the semiconductor structure 12 can be effectively transmitted through the light transmissive electrode 15 described below.

An example will be described below in which the semiconductor structure 12 is made of nitride semiconductors and the active layer 12c emits light having a peak wavelength of 455 nm. In this case, the refractive index of the first semiconductor layer 12a is about 2.4 and the refractive index of the light transmissive electrode 15, if made of indium tin oxide (ITO), is about 1.97. Accordingly, the cover part 21 is preferably made of SiN having a refractive index of about 2.01. This can reduce the reflection of light at the interface between the cover part 21 and the light transmissive electrode 15, thereby allowing more efficient extraction of the light traveling from the semiconductor structure 12 to the cover part 21.

The thickness of the cover part 21 is, for example, in a range of about 100 nm to 300 nm.

As shown in FIG. 1F, the cover part 21 may be composed of a plurality of layers.

FIG. 1F is a schematic partially enlarged cross-sectional view primarily showing the metal layer 13 disposed directly under an extended portion 16b and the surrounding cover part 21. The example of cover part 21 shown in FIG. 1F includes a first layer 21a disposed under the metal layer 13, a second layer 21b disposed above the metal layer 13, and a third layer 21c covering the second layer 21b and contacting the upper surface of the first semiconductor layer 12a. The first layer 21a, the second layer 21b, and the third layer 21c are made of a material similar to that of the cover part 21 described above.

When the cover part 21 is formed of the first layer 21a, the second layer 21b, and the third layer 21c, the metal layer 13 covered in the cover part 21 can be insulated from both the first semiconductor layer 12a positioned below the metal layer 13 and the light transmissive electrode 15 located on the upper and lateral sides of the metal layer 13.

The first layer 21a, the second layer 21b, and the third layer 21c may be made of materials different from one another, two layers of them may be made of the same material and one layer of them may be made of a material different from them, or all of these layers may be made of the same material. In the case in which two or more of the first layer 21a, the second layer 21b, and the third layer 21c are made of the same material, it might be difficult to distinguish them from each other. In such a case, these layers may be treated as an integrated body and deemed as a “cover part 21” like that shown in FIG. 1D.

The thickness of the first layer 21a can be set, for example, to 80 nm or more and 300 nm or less. Setting the thickness of the first layer 21a to 80 nm or more allows for more securely insulating the metal layer 13 from the first semiconductor layer 12a and facilitating effective reflection at the interface between the first layer 21a and the first semiconductor layer 12a. Setting the thickness of the first layer 21a to 300 nm or less allows for inhibiting the cover part 21 that includes the first layer 21a from becoming excessively thick, thereby reducing the occurrence of disconnection of the light transmissive electrode 15 formed on the cover part 21. In the present specification, the thickness of a member refers to the largest thickness of the member in a cross section.

The thickness of the second layer 21b can be set, for example, to 80 nm or more and 120 nm or less. Setting the thickness of the second layer 21b to 80 nm or more allows for more securely insulating the metal layer 13 from the light transmissive electrode 15. Setting the thickness of the second layer 21b to 120 nm or less allows for inhibiting the cover part 21 that includes the second layer 21b from becoming excessively thick, thereby reducing the occurrence of disconnection of the light transmissive electrode 15 formed on the cover part 21.

The thickness of the third layer 21c can be set, for example, to 100 nm or more and 500 nm or less. At the location directly below the external connection portion 16a, the third layer 21c reflects the light emitted by the active layer 12c, which allows for reducing the light absorption by the external connection portion 16a. Setting the thickness of the third layer 21c to fall within such a range allows for reducing the amount of light that is absorbed by the external connection portion 16a.

### Metal Layer 13

As shown in FIG. 1B and FIG. 1D, the metal layer 13 is disposed within the cover part 21 positioned between the first semiconductor layer 12a and the extended portions 16b of the first electrode 16. As shown in FIG. 1F, in the case in which the cover part 21 is composed of a first layer 21a, a second layer 21b, and a third layer 21c, the metal layer 13 is disposed within the cover part 21 by being positioned between the first layer 21a and the second layer 21b and being further covered by the third layer 21c.

The first layer 21a is in contact with the lower surface of the metal layer 13, the second layer 21b is in contact with the upper surface of the metal layer 13, and the third layer 21c is in contact with the lateral surfaces of the metal layer 13.

With the metal layer 13, the light that has not been reflected at the interface between the cover part 21 (the first layer 21a in case of a three-layer structure) and the first semiconductor layer 12a and have entered the cover part 21 (the first layer 21a) can be reflected by the metal layer 13 toward the first semiconductor layer 12a. This allows for increasing the output of the light emitting element 10A as compared to a case in which a metal layer 13 is not included in the cover part 21.

In this embodiment, as shown in FIG. 1B and FIG. 1C, the metal layer 13 is not located in a region of the cover part 21 between the first semiconductor layer 12a and the external connection portion 16a of the first electrode 16. This can reduce occurrence of the separation of the external connection portion 16a attributed to the metal layer 13 when performing wire-bonding to the external connection portion 16a.

The reflectance of the metal layer 13 for the peak wavelength of the light from the active layer 12c is higher than the reflectance of the first electrode 16 for the peak wavelength of the light from the active layer 12c. The metal layer 13 is made of a metal material having high reflectance for the peak wavelength of the light from the active layer 12c. For example, the metal layer 13 is made of a metal material having reflectance of 70% or higher, preferably 80% or higher, for the peak wavelength of the light from the active layer 12c. For the metal layer 13, for example, Al, Ag, or an alloy containing these metals can be used.

From the viewpoint of inhibiting the dissolution of the metal layer 13 in the solution used in patterning subsequent to forming the metal layer 13, AlCu, which is more corrosion-resistant than Al, is preferably used for the metal layer 13. The thickness of the metal layer can be set, for example, to 80 nm or more and 120 nm or less.

### Light Transmissive Electrode 15

A light transmissive electrode 15 is disposed on the upper surface of the cover part 21, and the portion of the upper surface of the first semiconductor layer 12a that is not covered by the cover part 21. The light transmissive electrode 15 is electrically connected to the first semiconductor layer 12a. A portion of the light transmissive electrode 15 is located between the first electrode 16 and the cover part 21. The light transmissive electrode 15 covering substantially the entire upper surface of the first semiconductor layer 12a can diffuse the current supplied to the first electrode 16 to a broader area of the first semiconductor layer 12a.

For the material of the light transmissive electrode 15, a metal oxide having conductivity is preferably used. The light transmissive electrode 15, for example, is an oxide containing at least one of the elements selected from the group consisting of Zn, In, Sn, Ga, and Ti. For example, for the light transmissive electrode 15, ITO, zinc oxide (ZnO), indium oxide (In₂O₃), tin oxide (SnO₂), or indium zinc oxide (IZO) can be used. ITO is particularly preferable for the light transmissive electrode 15 that covers substantially the entire upper surface of the first semiconductor layer 12a because of its high transmittance to visible light and high conductivity.

From the viewpoint of light absorption reduction, the thickness of the light transmissive electrode 15 is preferably smaller. The thickness of the light transmissive electrode 15 can be set, for example, to 30 nm or more and 100 nm or less, preferably 35 nm or more and 80 nm or less.

### First Electrode 16

A first electrode 16 includes an external connection portion 16a and an extended portion 16b extending from the external connection portion 16a disposed on the upper surface of the light transmissive electrode 15. The external connection portion 16a may be disposed on the upper surface of the light transmissive electrode 15.

The external connection portion 16a is a region for the external connection by wire bonding or the like. The external connection portion 16a has, for example, a substantially circular, quadrangular, or semielliptical shape in a plan view. In the example shown in FIG. 1A, the shape of the external connection portion 16a is substantially circular in a plan view.

The extended portion 16b is an auxiliary electrode for efficiently diffusing the current supplied via the external connection portion 16a to the light transmissive electrode 15. In a plan view, the width of an extended portion 16b is smaller than the width of the external connection portion 16a.

There are cases in which the external connection portion 16a can be easily distinguished from the extended portions 16b, and cases in which it cannot be easily distinguished.

In the case in which the border 16c between the external connection portion 16a and an extended portion 16b can be uniquely determined as in the case of the light emitting element 10A shown in FIG. 1A, the external connection portion 16a can be distinguished from the extended portion 16b using the border 16c as a reference.

In the example shown in FIG. 1A, because each extended portion 16b having a substantially constant width extends from the external connection portion 16a in a plan view, the border 16c between the external connection portion 16a and each extended portion 16b can be uniquely determined.

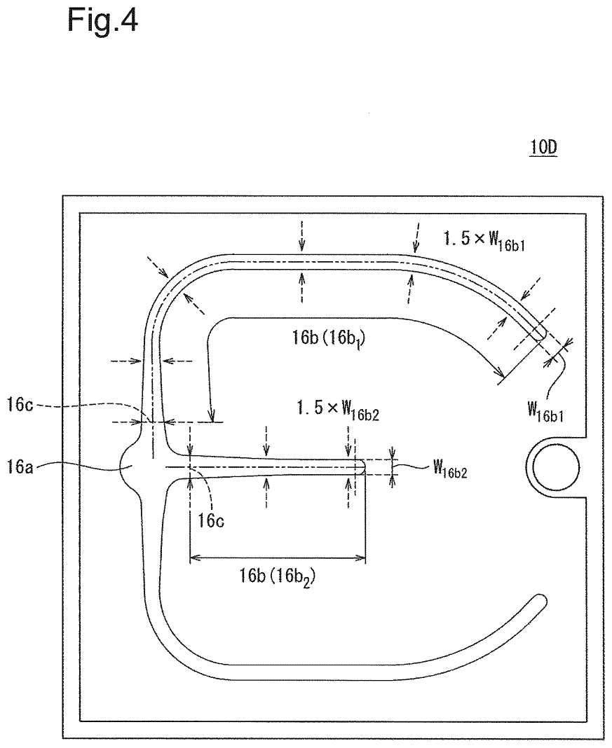

In the case of the light emitting element 10D shown in FIG. 4, it is difficult to uniquely determine the border 16c between the external connection portion 16a and an extended portion 16b. In the example shown in FIG. 4, it is difficult to determine the border 16c between the external connection portion 16a and each of the extended portions 16b because the width of each extended portion 16b extending from the external connection portion 16a is not constant in a plan view. In such a case, the border 16c between the external connection portion 16a and an extended portion 16b can be determined by the process described below.

In the light emitting element 10D shown in FIG. 4, the extended portions 16b include a curved extended portion 16b₁ and a straight extended portion 16b₂, and the tip of each of extended portion is rounded in a plan view.

In a curved extended portion 16b₁, the width is measured at a position near the tip where the edges of the extended portion 16b₁ become substantially parallel, designated as a reference width W_{16b1} for the extended portion 16b₁. As used herein, the term “width” of the extended portion 16b₁ is the dimension orthogonal to the extending direction of the extended portion 16b₁ in a plan view.

Then the width of the extended portion 16b₁ may be measured at multiple locations from the tip of the extended portion 16b₁ toward the external connection portion 16a. The position at which the width measured becomes equal to 1.5 times the reference width W_{16b1} will be designated as the border 16c between the external connection portion 16a and the extended portion 16b₁. In place of measuring the width of the extended portion 16b₁, a device can be used to determine whether or not the width at a position equals to 1.5 times the reference width W_{16b1}. For example, two parallel lines spaced to be equal to 1.5 times the reference width W16b₁ (1.5×W_{16b1}) drawn on a transparent sheet can be used as the device to identify the position at which the width equals to 1.5 times the reference width W_{16b1}.

Similarly, with respect to the straight extended portion 16b₂, the width is measured near the tip of the extended portion 16b₂ where the edges become substantially parallel, determined as a reference width W_{16b2} for the extended portion 16b₂.

Then the width of the extended portion 16b₂ may be measured at multiple locations from the tip of the extended portion 16b₂ toward the external connection portion 16a. The position at which the width measured equals to 1.5 times the reference width W_{16b2} will be determined as the border 16c between the external connection portion 16a and the extended portion 16b₂. The border 16c may be identified by using a device to determine whether or not the width equals to 1.5 times the reference width W_{16b2}.

In the light emitting element 10A according to this embodiment, a cover part 21 made of an insulating material is disposed between the first electrode 16 (the external connection portion 16a and the extended portions 16b) and the first semiconductor layer 12a of the semiconductor structure 12. In other words, the first electrode 16 is not in direct contact with the first semiconductor layer 12a. The first electrode 16 is electrically connected to the first semiconductor layer 12a via the light transmissive electrode 15. With this arrangement of a cover part 21, the current is less likely to flow from the first electrode 16 to the semiconductor structure 12 located directly below the first electrode. This can reduce the light emission of the semiconductor structure 12 directly below the first electrode 16, thereby reducing the light absorption by the first electrode 16. Further, the current flow to the semiconductor structure 12 can be increased in the area other than the region directly below the electrode 16, thereby allowing the light emitting element 10A to efficiently emit light.

For the external connection portion 16a of the first electrode 16, for example, Cu, Au, or an alloy containing these metals as main components can be employed because these are appropriate for external connection by wire bonding or the like. The external connection portion 16a and the extended portions 16b of the first electrode 16 may be made of the same material.

In a plan view of the light emitting element 10A, the extended portions 16b overlap the cover part 21 and the metal layer 13 at least in part. In other words, the metal layer 13 is disposed directly below at least some portions of the extended portions 16b. A portion of the light traveling from the active layer 12c toward the first electrode 16 is reflected by the metal layer 13. Accordingly, the absorption of light by the first electrode 16 can be reduced, so that the output of the light emitting element 10A can be increased.

In a plan view of the light emitting element 10A, moreover, the external connection portion 16a includes a first region 161 that overlaps the cover part 21 but not the metal layer 13. There is no interface between the cover part 21 and the metal layer 13 directly below the first region 161.

The weak adhesion between the cover part 21 and the metal layer 13 could allow for interfacial separation directly below the external connection portion 16a during wire bonding. This interfacial separation can lead to the separation between the semiconductor structure 12 and the external connection portion 16a.

In order to reduce such interfacial separation between the cover part 21 and the metal layer 13, the metal layer 13 is disposed such that the external connection portion 16a includes a first region 161 having no interface between the cover part 21 and the metal layer 13. With this structure, the external connection portion 16a is less likely to be separated from the semiconductor structure 12 when performing wire bonding to the external connection portion 16a.

From the viewpoint of inhibiting the separation of the external connection portion 16a, the external connection portion 16a is preferably the first region 161 in its entirety as shown in FIG. 1C.

The dimensions of the first electrode 16 can be suitably set by considering the dimensions of the light emitting element 10A.

As one example, the external connection portion 16a of the first electrode 16 has a maximum dimension of 50 μm to 100 μm, an area of 1950 μm² to 7850 μm², and the extended portions 16b are 2 μm to 10 μm in width when viewed from above. The thickness of the first electrode 16 is, for example, 0.5 μm to 4 μm. The thickness of the external connection portion 16a and the thicknesses of the extended portions 16b may be the same or different from each other.

### Second Electrode 17

A second electrode 17 is disposed on the second semiconductor layer 12b. The second electrode 17 is disposed on the upper surface of the second semiconductor layer 12b exposed at the bottom of the second exposed portion 12d2 which has substantially a semielliptical shape in a plan view.

For the second electrode 17, for example, Cu, Au, or an alloy having these metals as main components can be employed to be appropriate for external connection by wire bonding or the like.

### Protective Layer 20

A protective layer 20 is optionally included in the light emitting element 10A for covering and protecting substantially the entire upper surface side of the light emitting element 10A.

In the case of including a protective layer 20 in the light emitting element 10A, the protective layer 20 has an opening in which a portion of the upper surface of the external connection portion 16a of the first electrode 16 is exposed as shown in FIG. 1B and FIG. 1C. Wire-bonding to the external connection portion 16a is performed on the upper surface of the external connection portion 16a exposed at the opening of the protective layer 20. The protective layer 20 does not have to cover the lateral surfaces and a portion of the upper surface (near the outer edge) of the external connection portion 16a. In other words, the lateral surfaces and the upper surface of the external connection portion 16a may be exposed from the protective layer 20.

For the protective layer 20, a material having light transmissivity and insulating property is preferably used. For the protective layer 20, for example, SiO₂ or SiON can be used.

### Substrate 11

The light emitting element 10A optionally includes a substrate 11 for supporting the semiconductor structure 12. The substrate 11 may be a growth substrate for epitaxially growing the semiconductor structure 12. For the substrate 11, in the case of using nitride semiconductors for the semiconductor structure 12, for example, a sapphire (Al₂O₃) substrate can be used.

### Manufacturing Method

One example of a method of manufacturing a light emitting element 10A will be explained.

A semiconductor structure 12 including a second semiconductor layer 12b, an active layer 12c, and a first semiconductor layer 12a, and having an exposed portion 12d in which the second semiconductor layer 12b is exposed is provided on the upper surface of a substrate 11. The semiconductor structure 12 can be formed, for example, by MOCVD (metalorganic vapor deposition).

A metal layer 13 is formed in a cover part 21 at predetermined locations of the upper surface of the first semiconductor layer 12a (positions corresponding to the extended portions 16b of the first electrode 16 shown in FIG. 1). A metal layer 13 covered in the cover part 21 may be formed, for example, by two methods described below.

In a first method, a metal layer 13 is formed inside the cover part 21 that includes a first layer 21a, a second layer 21b, and a third layer 21c shown in FIG. 1F. First, a stack structure is formed by successively forming a first layer 21a made of an insulating material, a metal layer 13, and a second layer 21b made of an insulating material at predetermined positions (positions corresponding to the extended portions 16b) on the upper surface of the first semiconductor layer 12a. Then a third layer 21c made of an insulating material is formed to cover the upper surface and the lateral surfaces of the stack structure. Thus, a metal layer 13 disposed within the cover part 21 is formed.

In a second method, a metal layer 13 placed between the two layers made of an insulating material of the cover part 21.

First, a first insulating layer is formed at predetermined positions on the upper surface of the first semiconductor layer 12a (positions corresponding to the extended portions 16b). Then a metal layer 13 is formed at a location inward of the outer periphery of the first insulating layer in a plan view on the upper surface of the first insulating layer. Subsequently, a second insulating layer having substantially the same dimensions as those of the first insulating layer is formed to cover the upper surface and the lateral surfaces of the metal layer 13.

The metal layer 13 can be formed by a known film forming method, such as sputtering, chemical vapor deposition (CVD), or the like.

The cover part 21 can be formed, for example, by sputtering, chemical vapor deposition, or the like.

A light transmissive electrode 15 is formed on the upper surface and the lateral surfaces of the cover part 21 and the upper surface of the first semiconductor layer 12a not covered by the cover part 21. The light transmissive electrode 15 can be formed, for example, by sputtering. Then a first electrode 16 is formed at a predetermined location on the upper surface of the light transmissive electrode 15, and a second electrode 17 is formed at a predetermined location on the upper surface of the second semiconductor layer 12b exposed at the second exposed portion 12d2. The first electrode 16 and the second electrode 17 can be formed, for example, by sputtering.

Then, a protective layer 20 made of an insulating material is formed to cover the semiconductor structure 12, the light transmissive electrode 15, the extended portions 16b of the first electrode 16, the first exposed portion 12d1, and the second exposed portion 12d2. The protective layer 20 can be formed, for example, by sputtering, chemical vapor deposition, or the like. The protective layer 20 may partly cover the lateral surfaces and the upper surfaces of the first electrode 16 and the second electrode 17 to the extent that it does not interfere with wire bonding the external connection portion 16a of the first electrode 16 and the second electrode 17.

Forms that the light emitting element 10A according to this embodiment encompasses will be described in detail below. Light emitting elements 10A₂ to 10A₅ of Embodiment 1-1 to 1-4 will be described, focusing on the differences from the light emitting element 10A of Embodiment 1 while omitting the description of similar features.

### Embodiment 1-1

FIG. 1G is a schematic cross-sectional view of a light emitting element 10A₂ according to Embodiment 1-1, primarily showing the structure of the extended portions 16b of the first electrode 16 and its vicinity. The first layer 21a, the second layer 21b, and the metal layer 13 of the light emitting element 10A of Embodiment 1 shown in FIG. 1F are substantially constant in thickness at both lateral ends and the central portion thereof in a cross section. In comparison, in the first variation, the thicknesses of these layers vary laterally. FIG. 1G is a schematic cross section corresponding to that taken along 1d-1d in FIG. 1A.

In the light emitting element 10A₂ of Embodiment 1-1, in the cross section, the thicknesses of the first layer 21a, the second layer 21b, and the metal layer 13 are smaller at both lateral ends and larger in the central portion. The thickness of the metal layer 13 being smaller at both ends than at the central portion allows the first layer 21a and the second layer 21b to easily cover the end portions of the metal layer 13. With this structure, the metal layer 13 is less likely to be affected by the external environment and thus is less likely to be modified or degraded, thereby improving the reliability of the light emitting element 10A₂.

### Embodiment 1-2

FIG. 1H and FIG. 1I are schematic cross-sectional views of a light emitting element 10A₃ according to Embodiment 1-2. FIG. 1H illustrates the structure around the external connection portion 16a of the first electrode 16, and FIG. 1I illustrates the structure around an extended portion 16b of the first electrode 16.

As shown in FIG. 1H, the first electrode 16 of the light emitting element 10A₃ according to Embodiment 1-2 includes a reflecting electrode 22a located between the light transmissive electrode 15 and the external connection portion 16a. The reflecting electrode 22a has a higher reflectance for the peak wavelength of the light emitted by the active layer 12c than that of the external connection portion 16a.

In a plan view of the light emitting element 10A₃, the first region 161, which overlaps the cover part 21 but does not overlap the metal layer 13, of the external connection portion 16a overlaps the reflecting electrode 22a. With the first region 161 not overlapping the metal layer 13, the light traveling from the active layer 12c toward the first region 161 of the external connection portion 16a cannot be reflected by the metal layer 13. The light emitting element 10A₃ according to the second variation includes a reflecting electrode 22 at a position that overlaps the first region 161, allowing the reflecting electrode 22 to reflect the light heading from the active layer 12c toward the first region 161. This can reduce the absorption of light by the external connection portion 16a, thereby further increasing the output of the light emitting element 10A₃. The reflectance of the reflecting electrode 22a for the peak wavelength of the light emitted by the active layer 12c may be lower than the reflectance of the metal layer 13 for the peak wavelength of the light emitted by the active layer 12c. On the other hand, the adhesion between the reflecting electrode 22a and the cover part 21 can be higher than the adhesion between the metal layer 13 and the cover part 21.

In a plan view of the light emitting element 10A₃, the outer edges of the reflecting electrode 22a are preferably located outward of the outer edges of the external connection portion 16a. In other words, in a plan view, the reflecting electrode 22a is preferably larger than the external connection portion 16a as well as completely overlapping the external connection portion 16a. In a cross-sectional view such as FIG. 1H, the width W22a of the reflecting electrode 22a is larger than the width W16a of the external connection portion 16a. This size relationship between the width W22a of the reflecting electrode 22a and the width W16a of the external connection portion 16a is established in the same cross section, irrespective of the relationship between the width W22a of the reflecting electrode 22a in one cross section and the width W16a of the external connection portion 16a in another cross section.

The “width” of the reflecting electrode 22a in a cross section refers to a dimension in the direction orthogonal to the thickness direction of the reflecting electrode 22a, and the “width” of the external connection portion 16a in a cross section refers to a dimension in the direction orthogonal to the thickness direction of the external connection portion 16a.

With this configuration, the reflecting electrode 22a can be located across the entire paths of rays of light travelling from the active layer 12c toward the first region 161 of the external connection portion 16a, thereby further increasing the output of the light emitting element 10A₃.

The reflecting electrode 22a is made of a conductive material, for example, a single or multilayer structure composed of a metal or alloy. An example of a multilayer structure is one that stacks a Rh—Cr alloy layer and a Pt layer from the light transmissive electrode 15 side. The reflecting electrode 22a can have a light reflecting function and a function to achieve good contact with the light transmissive electrode 15.

As shown in FIG. 1I, the reflecting electrode 22b is preferably also provided between the light transmissive electrode 15 and the extended portions 16b. As shown in FIG. 1I, the width W13 of the metal layer 13 is preferably larger than the width W22b of the reflecting electrode 22b when the metal layer 13 and the reflecting electrode 22b are both present directly under the extended portions 16b. Here, the “width” of the metal layer 13 and the “width” of the extended portions 16b are dimensions orthogonal to the direction in which they extend in a plan view. FIG. 1I is a cross-sectional view taken along a plane that is orthogonal to the extending direction of an extended portion 16b, and the width W13 of the metal layer 13 and the width 22b of the reflecting electrode 22b are the dimensions in the direction orthogonal to the extending direction of the extended portion 16b.

In the case in which an extended portion 16b is straight, the extending direction is a straight line, and the direction orthogonal to the extending direction is determined uniquely. On the other hand, in the case in which an extended portion 16b is partly bent or curved, the extending direction is also bent or curved. A direction “orthogonal” to a bent or curved extending direction refers to one that is orthogonal to the tangent line drawn to be tangent to the bent or curved extending direction at a point where the width is measured.

As shown in FIG. 1I, furthermore, the width W22b of the reflecting electrode 22b is preferably larger than the width W16b of the extended portion 16b. The “width” of the extended portion 16b refers to the maximum dimension in the direction orthogonal to the extending direction of the extended portion 16b in a plan view.

Such a configuration allows the reflecting electrode 22b to be provided across the entire paths of rays of light travelling from the active layer 12c toward the extended portions 16b. so that the output of the light emitting element 10A₃ can be further increased.

### Embodiments 1-3 and 1-4

FIG. 1J is a schematic cross-sectional view of a light emitting element 10A₄ according to Embodiment 1-3, and FIG. 1K is a schematic cross-sectional view of a light emitting element 10A₅ according to Embodiment 1-4. FIG. 1J and FIG. 1K each illustrate the structure around the external connection portion 16a of the first electrode 16.

As shown in FIG. 1J and FIG. 1K, the external connection portion 16a in the light emitting element 10A₄ according to the third variation and the light emitting element 10A₅ according to the fourth variation may include a third region 163 which does not overlap the cover part 21 and the metal layer 13 in a plan view. With the third region 163 in which the cover part 21 is absent between the light transmissive electrode 15 and the semiconductor structure 12, the contact area between the light transmissive electrode 15 and the semiconductor structure 12 can be increased, thereby reducing the forward voltage (Vf) of the light emitting elements 10A₄ and 10A₅.

In order to sufficiently exhibit the effect of providing the cover part 21, the area of the third region 163 is preferably controlled to be in an appropriate range. In a plan view of the light emitting elements 10A₄ and 10A₅, the area of the third region 163 is preferably set to 30% to 70% of the area in which the external connection portion 16a overlaps the cover part 21.

As shown in FIG. 1J, in one example of light emitting element 10A₄ which includes a third region 163, the third region 163 is located inward of the outer edges of the cover part 21 in a plan view. In a cross-sectional view of the light emitting element 10A₄, as shown in FIG. 1J, the third region 163 of the external connection portion 16a is surrounded by the first region 161 that overlaps the cover part 21.

As shown in FIG. 1K, in another example of light emitting element 10A₅ which includes a third region 163, the third region 163 is located outward of the outer edges of the cover part 21 in a plan view. In a cross-sectional view of the light emitting element 10A₅, as shown in FIG. 1K, the third region 163 of the external connection portion 16a surrounds the first region 161.

### Embodiment 2

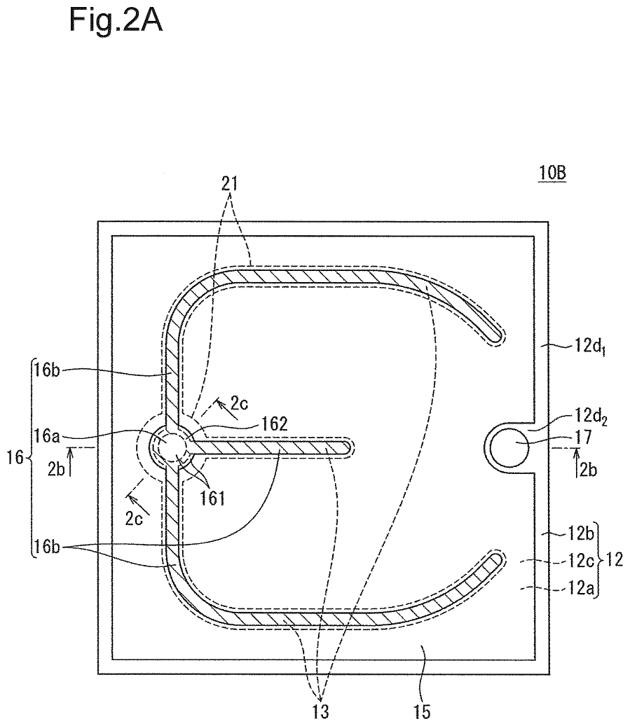

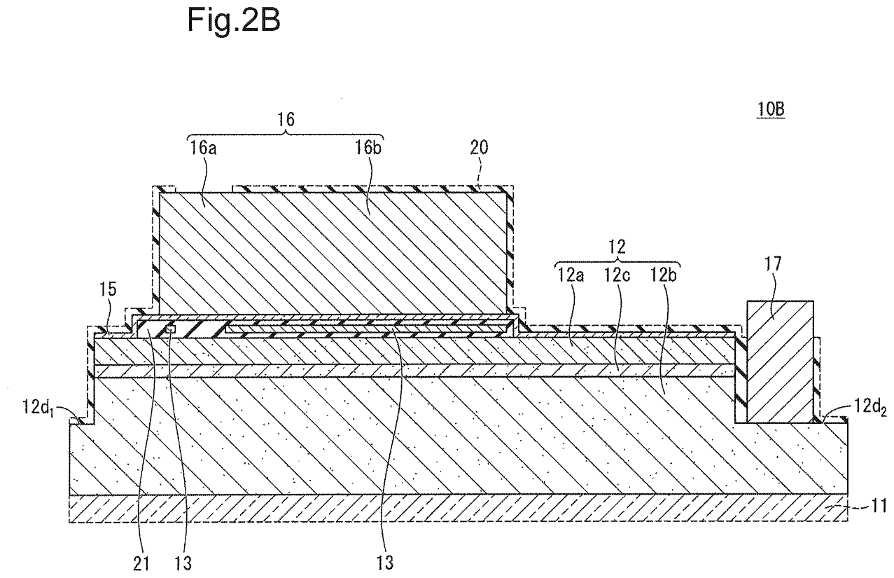

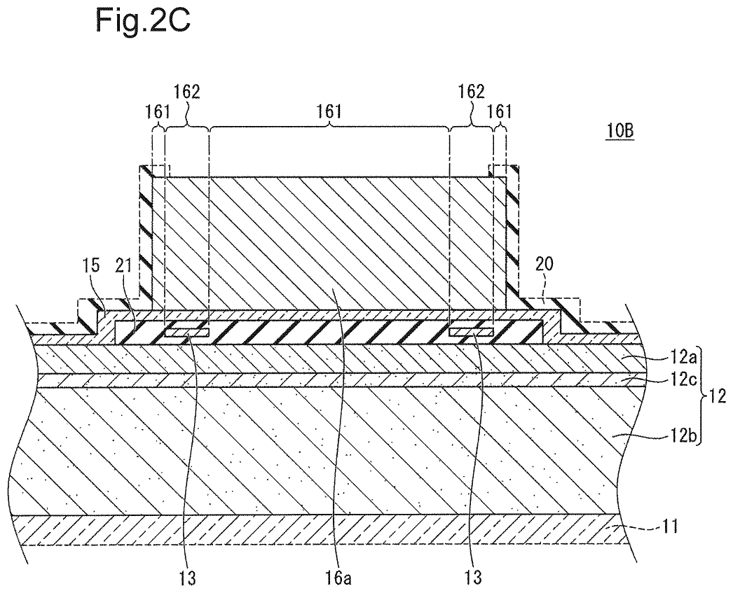

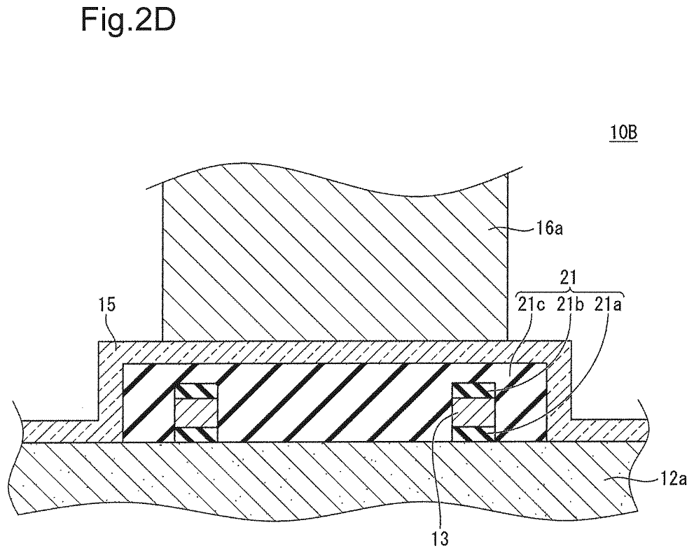

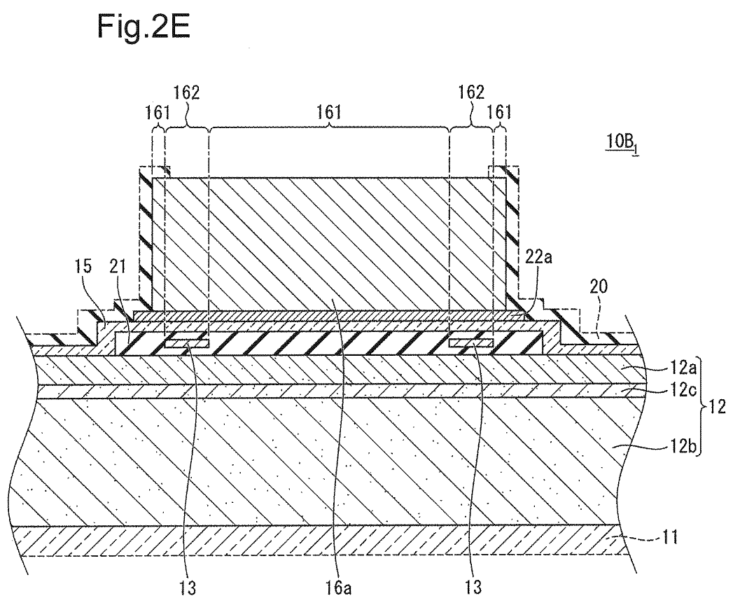

A light emitting element 10B according to Embodiment 2 will be described below with reference to FIG. 2A to FIG. 2E. The differences from the light emitting element 10A according to Embodiment 1 will be primarily explained. Detailed description of similar features and materials to those of the light emitting element 10A according to Embodiment 1 will be omitted.

FIG. 2A is a schematic plan view of a light emitting element 10B according to Embodiment 2. FIG. 2B is a schematic cross-sectional view taken along line 2b-2b in FIG. 2A. FIG. 2C is a schematic partial cross-sectional view taken along line 2c-2c in FIG. 2A, primarily showing the structure around the external connection portion 16a of the first electrode 16.

The light emitting element 10B according to Embodiment 2 differs from Embodiment 1 such that the external connection portion 16a of the first electrode 16 partially overlaps the metal layer 13 in a plan view. In other words, in the light emitting element 10B according to Embodiment 2, the external connection portion 16a includes a first region 161, which does not overlap the metal layer 13, and a second region 162, which overlaps the metal layer 13. In the example shown in FIG. 2A, the second region 162 is annular.

As shown in FIG. 2A, in a plan view of the light emitting element 10B, at least a portion of the first region 161 is surrounded by the metal layer 13. The metal layer 13 may overlap the external connection portion 16a. In other words, as shown in FIG. 2C, the external connection portion 16a may include a second region 162 which overlaps the cover part 21 and the metal layer 13. As shown in FIG. 2A and FIG. 2C, the first region 161 may be further provided outward of the second region 162.

With the metal layer 13 disposed directly below the second region 162 of the external connection portion 16a, a portion of the light traveling from the active layer 12c toward the external connection portion 16a is reflected by the metal layer 13 before reaching the external connection portion 16a, and thus is extracted from the light emitting element 10B. This can reduce the light absorption by the external connection portion 16a, thereby increasing the output of the light emitting element 10B.

In the case of providing a second region 162, the area of the second region 162 is preferably controlled to be in an appropriate range. In a plan view of the light emitting element 10B, the area of the second region 162 is preferably set to 10% or more and 40% or less of the area of the external connection portion 16a.

With the presence of an interface between the metal layer 13 and the cover part 21 directly below the second region 162 of the external connection portion 16a, interfacial separation may occur when wire bonding the external connection portion 16a, which might induce the separation of the external connection portion 16a from the semiconductor structure 12. In order to reduce interfacial separation as much as possible, as shown in FIG. 2C, it is preferable that the metal layer 13 is not located directly below the center of the external connection portion 16a which is to be subjected to the maximum shock during wire bonding. In other words, the first region 161 is preferably located in a region that includes the center of the external connection portion 16a in a plan view as shown in FIG. 2A.

The metal layer 13 disposed directly under the second region 162 of the external connection portion 16a can have a configuration similar to that of the metal layer 13 disposed directly under the extended portions 16b. For example, as shown in FIG. 2E, similar to FIG. 1F of Embodiment 1, the cover part 21 that covers the metal layer 13 can be composed of a first layer 21a, a second layer 21b, and a third layer 21c.

As shown in FIG. 2E, similar to FIG. 1H of Embodiment 1, in a plan view of the light emitting element 10B, the first region 161, which overlaps the cover part 21 but does not overlap the metal layer 13, of the external connection portion 16a preferably overlaps the reflecting electrode 22a. The reflecting electrode 22a does not have to overlap the second region 162, but more preferably overlaps the second region 162.

### Embodiment 3

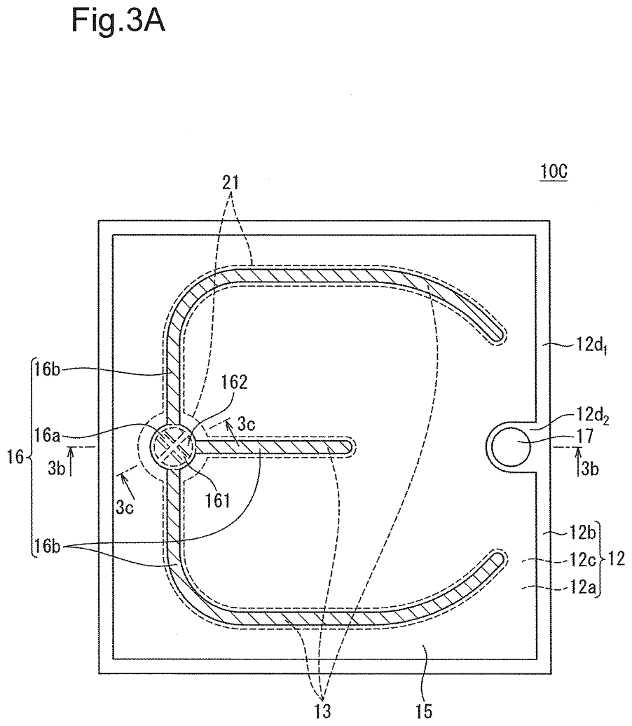

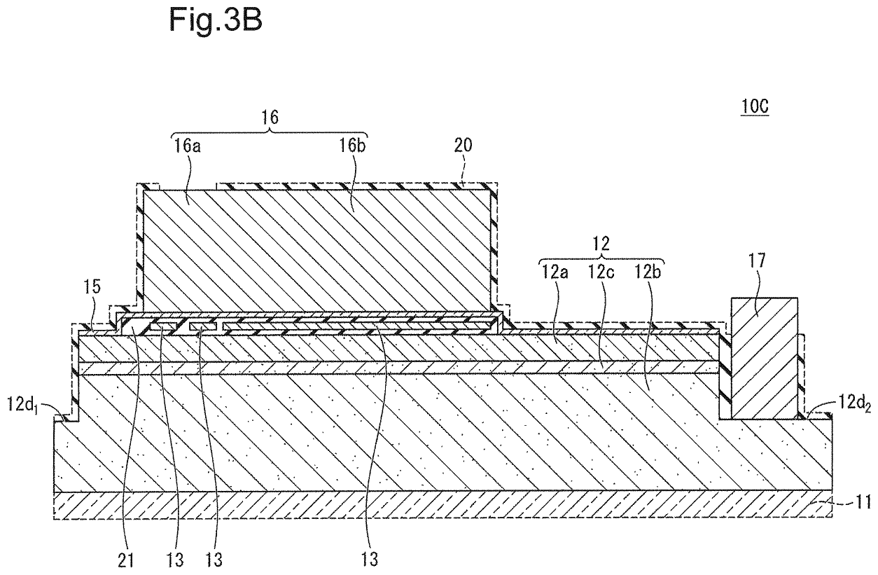

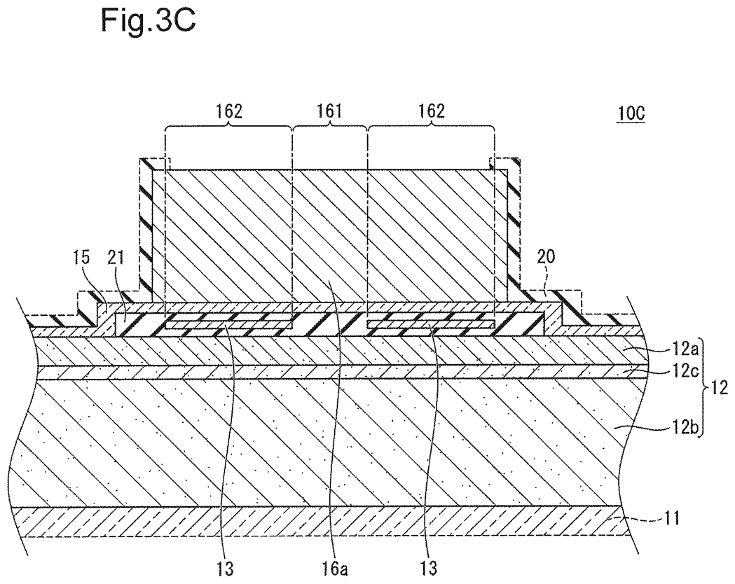

A light emitting element 10C according to Embodiment 3 will be described below with reference to FIG. 3A to FIG. 3C. The differences from the light emitting elements 10A and 10B according to Embodiments 1 and 2 will be primarily explained. Detailed description of similar features and materials to those of the light emitting elements 10A and 10B according to Embodiments 1 and 2 will be omitted.

FIG. 3A is a schematic plan view of a light emitting element 10C according to Embodiment 3. FIG. 3B is a schematic cross-sectional view taken along line 3b-3b in FIG. 3A. FIG. 3C is a schematic cross-sectional view taken along line 3c-3c in FIG. 3A primarily showing the structure around the external connection portion 16a of the first electrode 16.

The light emitting element 10C according to Embodiment 3 differs from Embodiment 2 such that the metal layer 13 overlapping the external connection portion 16a of the first electrode 16 are divided into multiple sections. In other words, in the light emitting element 10C according to Embodiment 3, the external connection portion 16a includes a plurality of second regions 162. In the example shown in FIG. 3A, the external connection portion 16a includes four second regions 162.

As shown in FIG. 3A, the plurality of second regions 162 are included in the light emitting elements 10C in a plan view of the light emitting elements 10C. A first region 161 is provided between two second regions 162 adjacent to each other in a plan view.

With the metal layer 13 disposed directly under the second region 162 of the external connection portion 16a, a portion of the light traveling from the active layer 12c towards the external connection portion 16a is reflected by the metal layer 13 before reaching the external connection portion 16a, and thus is extracted from the light emitting element 10C. This can reduce the light absorption by the external connection portion 16a, thereby increasing the output of the light emitting element 10C.

In order to reduce the chances of interfacial separation as much as possible, as shown in FIG. 3B, similar to Embodiment 2, it is preferable that the metal layer 13 is not located directly below the center of the external connection portion 16a, which is to be subjected to the maximum shock during wire bonding. In other words, as shown in FIG. 3A, the first region 161 is preferably located in a region that includes the center of the external connection portion 16a in a plan view.

Similar to Embodiment 2, the cover part 21 enclosing the metal layer 13 disposed directly below the plurality of second regions 162 of the external connection portion 16a can be composed of a first layer, a second layer, and a third layer (not shown).

In the foregoing, light emitting elements according to embodiments of the present invention have been specifically described based on forms of implementing the invention. The present invention, however, is not limited to these described above, and must be broadly interpreted based on the scope of the claims. Various changes and modifications made based on the description above are encompassed by the spirit of the invention.

Light emitting elements according to the present invention can be utilized as various light sources, such as backlight light sources of liquid crystal displays, various lighting fixtures, large displays, and the like.

What is claimed is:

1. A light emitting element comprising:
a semiconductor structure comprising:
a first semiconductor layer of a first conductivity type,
an active layer disposed below the first semiconductor layer, and a second semiconductor layer of a second conductivity type disposed below the active layer;
a cover part made of an insulating material and disposed on an upper surface of the first semiconductor layer;
a metal layer disposed within the cover part;
a light transmissive electrode disposed on an upper surface of the cover part and the upper surface of the first semiconductor layer;
a first electrode comprising:
an external connection portion disposed on an upper surface of the light transmissive electrode, and
an extended portion extending from the external connection portion; and
a second electrode disposed on the second semiconductor layer; wherein:
at least a portion of the extended portion overlaps the cover part and the metal layer in a plan view; and
the external connection portion comprises a first region overlapping the cover part and not overlapping the metal layer in the plan view.

2. The light emitting element according to claim 1, wherein:
the cover part comprises:
a first layer disposed below the metal layer,
a second layer disposed on the metal layer, and
a third layer covering the second layer and being in contact with the upper surface of the first semiconductor layer.

3. The light emitting element according to claim 1, wherein an entirety of the external connection portion is the first region.

4. The light emitting element according to claim 1, wherein at least a portion of the first region is surrounded by the metal layer in the plan view.

5. The light emitting element according to claim 1, wherein the first region includes a center of the external connection portion in the plan view.

6. The light emitting element according to claim 1, wherein the external connection portion further comprises one or more second regions that overlaps the cover part and the metal layer in the plan view.

7. The light emitting element according to claim 6, wherein the external connection portion comprises a plurality of the second regions.

8. The light emitting element according to claim 1, wherein:
the first electrode further comprises, between the light transmissive electrode and the external connection portion, a reflecting electrode having a higher reflectance for the peak wavelength of the light emitted by the active layer than that of the external connection portion, and
the first region overlaps the reflecting electrode in the plan view.

9. The light emitting element according to claim 8, wherein an outer edge of the reflecting electrode is located outward of an outer edge of the external connection portion in the plan view.

10. The light emitting element according to claim 8, wherein the reflecting electrode is further provided between the light transmissive electrode and the extended portion.

11. The light emitting element according to claim 10, wherein a width of the metal layer is larger than a width of the reflecting electrode in a direction orthogonal to an extending direction of the extended portion.

12. The light emitting element according to claim 1, wherein the external connection portion further comprises a third region that does not overlap the cover part and the metal layer in the plan view.

13. The light emitting element according to claim 12, wherein, in the plan view, an area of the third region is 30% to 70% of an area in which the external connection portion overlaps the cover part.

14. The light emitting element according to claim 12, wherein the third region is located inward of an outer edge of the cover part in the plan view.

15. The light emitting element according to claim 12, wherein the third region is located outward of an outer edge of the cover part in the plan view.

16. A light emitting element comprising:
a semiconductor structure comprising:
a first semiconductor layer of a first conductivity type,
an active layer disposed below the first semiconductor layer, and
a second semiconductor layer of a second conductivity type disposed below the active layer;
a cover part disposed on an upper surface of the first semiconductor layer and containing one or more elements selected from Zr, Si, V, Nb, Hf, Ta, Al, Ce, In, Sb, and Zn, and either one or both of oxygen and nitrogen;
a metal layer disposed within the cover part;
a light transmissive electrode disposed on an upper surface of the cover part and the upper surface of the first semiconductor layer;
a first electrode comprising:
an external connection portion disposed on an upper surface of the light transmissive electrode, and
an extended portion extending from the external connection portion; and
a second electrode disposed on the second semiconductor layer; wherein:
at least a portion of the extended portion overlaps the cover part and the metal layer in the plan view; and
the external connection portion comprises a first region overlapping the cover part and not overlapping the metal layer in the plan view.
